(19) United States
(12) Patent Application Publication
(10) Pub. No.: US 2023/0072887 A1
(43) Pub. Date: Mar. 9, 2023

(54) SEMICONDUCTOR MANUFACTURING APPARATUS AND METHOD OF MANUFACTURING SEMICONDUCTOR DEVICE

(71) Applicant: Kioxia Corporation, Tokyo (JP)

(72) Inventors: Fuyuma ITO, Yokkaichi Mie (JP); Hiroyasu IIMORI, Nagoya Aichi (JP); Shinsuke MURAKI, Kuwana Mie (JP); Yuya AKEBOSHI, Yokkaichi Mie (JP); Yosuke MARUYAMA, Yokkaichi Mie (JP); Satoshi NAKAOKA, Yokkaichi Mie (JP)

(73) Assignee: Kioxia Corporation, Tokyo (JP)

(21) Appl. No.: 17/691,209

(22) Filed: Mar. 10, 2022

(30) Foreign Application Priority Data
Sep. 8, 2021 (JP) 2021-146477

(51) Int. Cl. H01L 21/66; H01L 21/67

(52) U.S. Cl. CPC H01L 22/12; H01L 21/67051; H01L 21/67063

(57) ABSTRACT

In one embodiment, a semiconductor manufacturing apparatus includes a processor configured to process a film provided on an end portion of a substrate. The apparatus further includes a detector configured to detect information relating to a shape of the end portion of the substrate. The apparatus further includes a controller configured to control the processing of the film by the processor, based on the information relating to the shape of the end portion of the substrate.

### CROSS REFERENCE TO RELATED APPLICATION

This application is based upon and claims the benefit of priority from the prior Japanese Patent Application No. 2021-146477, filed on Sep. 8, 2021, the entire contents of which are incorporated herein by reference.

### FIELD

Embodiments described herein relate to a semiconductor manufacturing apparatus and a method of manufacturing a semiconductor device.

### BACKGROUND

When a film on a substrate is to be processed (e.g., etched), it is difficult in some cases to suitably process the film provided on an end portion of the substrate.

### BRIEF DESCRIPTION OF THE DRAWINGS

FIG. 1 is a cross-sectional view schematically illustrating a structure of a semiconductor manufacturing apparatus of a first embodiment;

FIGS. 2A to 2C are cross-sectional views for describing a method of manufacturing a semiconductor device of the first embodiment;

FIGS. 3A and 3B are cross-sectional views illustrating examples of a detector of the first embodiment;

FIGS. 4A and 4B are cross-sectional views for describing the operation of a chemical solution supplier of the first embodiment.

FIG. 5 is a cross-sectional view illustrating a structure of a semiconductor manufacturing apparatus of a first modification of the first embodiment;

FIGS. 6A and 6B are perspective views illustrating structures of semiconductor manufacturing apparatuses of second and third modifications of the first embodiment;

FIGS. 7A and 7B are cross-sectional views illustrating structures of semiconductor manufacturing apparatuses of fourth and fifth modifications of the first embodiment; and

FIGS. 8A to 8C are cross-sectional views illustrating a method of manufacturing a semiconductor device of a second embodiment.

### DETAILED DESCRIPTION

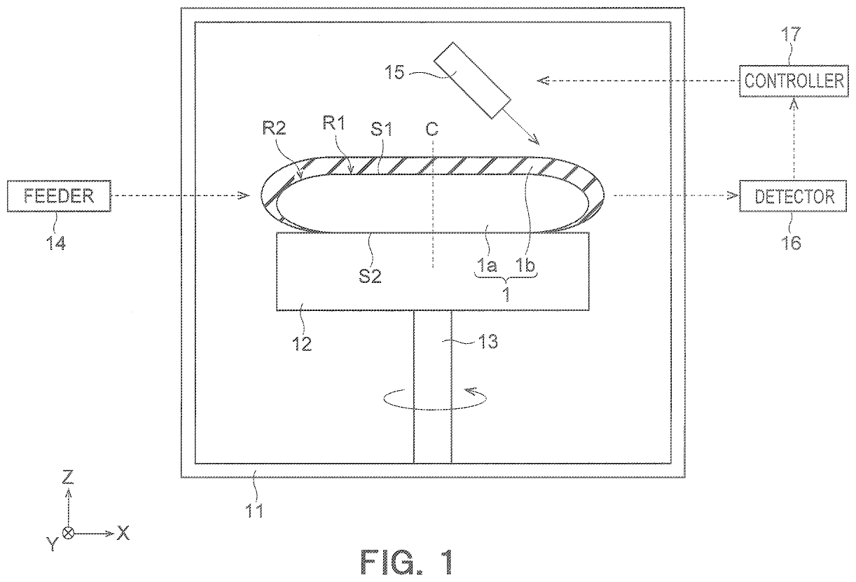

Embodiments will now be explained with reference to the accompanying drawings. In FIGS. 1 to 8C, the same configurations are denoted by the same reference characters, and overlapping descriptions are omitted.

In one embodiment, a semiconductor manufacturing apparatus includes a processor configured to process a film provided on an end portion of a substrate. The apparatus further includes a detector configured to detect information relating to a shape of the end portion of the substrate. The apparatus further includes a controller configured to control the processing of the film by the processor, based on the information relating to the shape of the end portion of the substrate.

### First Embodiment

FIG. 1 is a cross-sectional view schematically illustrating a structure of a semiconductor manufacturing apparatus of a first embodiment.

The semiconductor manufacturing apparatus of the present embodiment includes a processing chamber 11 that is an example of a container, a stage 12, a rotational shaft 13, a feeder 14, a chemical solution supplier 15 that is an example of a processor, a detector 16, and a controller 17. A semiconductor processing apparatus of the present embodiment is used for processing a processing target substrate 1, for example.

FIG. 1 illustrates an X direction, a Y direction, and a Z direction perpendicular to each other. In the present description, a +Z direction is processed as an upper direction, and a −Z direction is processed as a lower direction. The −Z direction may match with the gravity direction or may not match with the gravity direction.

The processing target substrate 1 of the present embodiment includes a substrate 1a and a film 1b provided on the substrate 1a. The substrate 1a is a semiconductor wafer such as a silicon wafer, for example. FIG. 1 illustrates a front face (upper face) S1 of the substrate 1a, a rear face (lower face) S2 of the substrate 1a, and a central axis C of the substrate 1a. The substrate 1a includes a central portion R1 having the front face S1 and the rear face S2 that are generally flat, and a bevel portion (round portion) R2 having the front face S1 and the rear face S2 that are curved. In FIG. 1, the front face S1 and the rear face S2 of the central portion R1 are parallel to the X direction, parallel to the Y direction, and perpendicular to the Z direction. The film 1b of the present embodiment is formed on the central portion R1 and the bevel portion R2. The film 1b includes various device layers, interconnect layers, plug layers, electrode layers, and inter layer dielectrics, for example. In the present embodiment, the film 1b includes a silicon oxide film as the inter layer dielectric, and the silicon oxide film is formed on the central portion R1 and the bevel portion R2. The bevel portion R2 is an example of the end portion of the substrate 1a.

The semiconductor processing apparatus of the present embodiment is a wet etching apparatus, for example, and is used to etch the film 1b with a chemical solution. The chemical solution (etching solution) of the present embodiment may be any liquid as long as the film 1b can be etched. Further details of the etching are described below.

Next, each component of the semiconductor manufacturing apparatus of the present embodiment is described.

The processing chamber 11 can contain the processing target substrate 1. The processing target substrate 1 of the present embodiment is placed on the stage 12 in the processing chamber 11 and is rotated about a rotational shaft C by the rotational shaft 13. The stage 12 is installed in the processing chamber 11, and the rotational shaft 13 is attached to a lower face of the stage 12 in the processing chamber 11. The rotational shaft 13 can rotate the processing target substrate 1 on the stage 12 by rotating the stage 12.

The feeder 14 feeds the processing target substrate 1 in the semiconductor manufacturing apparatus of the present embodiment. The feeder 14 can feed the processing target substrate 1 into the processing chamber 11 and feed out the processing target substrate 1 from the processing chamber 11, for example.

The chemical solution supplier 15 supplies the chemical solution to the processing target substrate 1 on the stage 12 and processes (etches) the film 1b with the chemical solution. The etching is performed in order to remove the film 1b formed on the bevel portion R2 of the substrate 1a by etching, for example. The chemical solution supplier 15 of the present embodiment includes a nozzle that discharges the chemical solution to the film 1b, and FIG. 1 illustrates one example of the nozzle of the chemical solution supplier 15.

The detector 16 detects information relating to the processing target substrate 1 and detects information (bevel information) relating to the shape of the bevel portion R2 of the substrate 1a, for example. The detector 16 may detect the information such as the bevel information from the processing target substrate 1 outside of the processing chamber 11, but the information such as the bevel information is detected from the processing target substrate 1 in the processing chamber 11 in the present embodiment. This makes it possible to recognize the state of the processing target substrate 1 immediately before the processing target substrate 1 is processed. FIG. 1 illustrates how the bevel information is detected from the processing target substrate 1 in a state in which the processing target substrate 1 is placed on the stage 12. As described below, the detector 16 may detect the bevel information in a form of image data or optical measurement data. The detector 16 may further detect information (warp information) relating to the warp of the substrate 1a, information (notch information) relating to a notch in the substrate 1a, and information (eccentricity amount information) relating to the eccentricity amount of the substrate 1a.

The controller 17 controls various operations of the semiconductor manufacturing apparatus. The controller 17 controls the rotation of the processing target substrate 1 by the rotational shaft 13, the feeding of the processing target substrate 1 by the feeder 14, the supplying of the chemical solution by the chemical solution supplier 15, and the detection of information by the detector 16, for example. In the present embodiment, the detector 16 outputs a detection result of the information relating to the processing target substrate 1, and the controller 17 controls the processing (etching) of the film 1b by the chemical solution supplier 15 based on the detection result. For example, the controller 17 controls the etching of the film 1b on the bevel portion R2 based on the bevel information, the warp information, the notch information, and the eccentricity amount information. Further details of the control are described below.

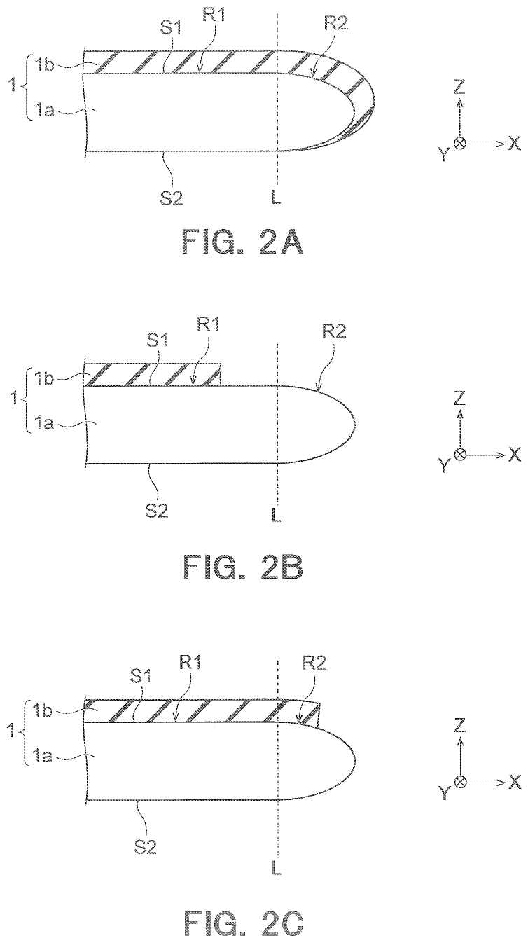

FIGS. 2A to 2C are cross-sectional views for describing a method of manufacturing a semiconductor device of the first embodiment.

As with FIG. 1, FIG. 2A illustrates the processing target substrate 1 before the etching. FIG. 2A further illustrates a boundary plane L between the central portion R1 and the bevel portion R2 of the substrate 1a. The shape of the boundary plane L of the present embodiment is a side face shape of a cylindrical shape, for example. The width of the bevel portion R2 in planar view, that is, the difference between the outer diameter and the inner diameter of the bevel portion R2 is from 0.1 mm to 1.0 mm, for example. The shape of the processing target substrate 1 changes to the shape illustrated in FIG. 2B or 2C, for example, by etching performed by the chemical solution supplier 15.

FIG. 2B illustrates an example of the processing target substrate 1 after the etching. In FIG. 2B, a part of the film 1b on the central portion R1 is removed and all of the film 1b on the bevel portion R2 is removed. In FIG. 2B, a cutting position of the film 1b is positioned on the central portion R1.

FIG. 2C illustrates another example of the processing target substrate 1 after the etching. In FIG. 2C, the film 1b on the central portion R1 is not removed and a part of the film 1b on the bevel portion R2 is removed. In FIG. 2C, a cutting position of the film 1b is positioned on the bevel portion R2. In other words, the film 1b is partially remaining on the bevel portion R2.

The substrate 1a of the present embodiment is bonded to another substrate via the film 1b after the film 1b is etched, for example. In this case, in order to suitably perform the bonding, it is desired to etch the film 1b into the shape illustrated in FIG. 2C than to etch the film 1b into the shape illustrated in FIG. 2B. Therefore, the controller 17 of the present embodiment controls the chemical solution supplier 15 such that the film 1b is etched into the shape illustrated in FIG. 2C when the film 1b is etched by the chemical solution supplier 15. The controller 17 realizes such etching by controlling the position and the angle of the abovementioned nozzle (chemical solution supplier 15) with respect to the substrate 1a based on the bevel information, for example. This makes it possible to etch the film 1b into a shape suitable for bonding. The film 1b of the present embodiment may be etched into the shape illustrated in FIG. 2C for a purpose different from bonding.

An example of structures and operations of the chemical solution supplier 15, the detector 16, the controller 17, and the like for a case where the film 1b is etched into the shape illustrated in FIG. 2C is described below.

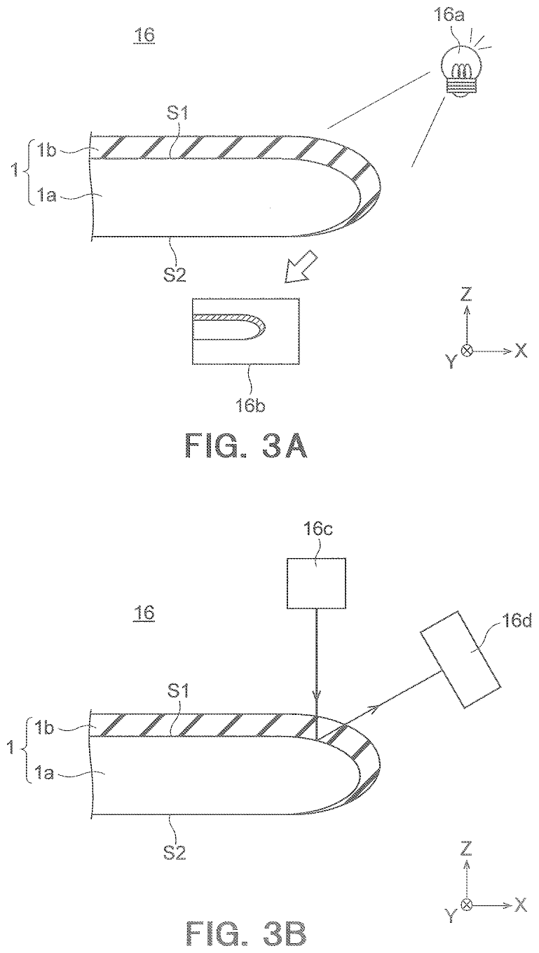

FIGS. 3A and 3B are cross-sectional views illustrating examples of the detector 16 of the first embodiment.

In the example of FIG. 3A, the detector 16 includes a light source 16a and an imager 16b. The light source 16a irradiates the substrate 1a with light. The imager 16b images the substrate 1a in a state in which the light source 16a is irradiating the substrate 1a with light. A large part of the film 1b of the present embodiment is formed by a silicon oxide film, and the silicon oxide film is transparent. Therefore, the imager 16b can also image the part covered with the film 1b in the substrate 1a. Many more parts of the film 1b on the bevel portion R2 of the present embodiment are formed by the silicon oxide film. Therefore, the bevel portion R2 can be suitably imaged. The imager 16b can detect the bevel information, the warp information, the notch information, and the eccentricity amount information described above in the form of image data by the imaging. The controller 17 can extract the bevel information, the warp information, the notch information, and the eccentricity amount information described above from the image data by image processing using the image data.

In the example in FIG. 3B, the detector 16 includes a light emitter 16c and a light receiver 16d. The light emitter 16c generates light such as laser light. The light generated from the light emitter 16c is reflected by the substrate 1a and enters the light receiver 16d. A large part of the film 1b of the present embodiment is formed by a silicon oxide film, and the silicon oxide film is transparent. Therefore, the light from the light emitter 16c can also enter the part covered with the film 1b in the substrate 1a. Many more parts of the film 1b on the bevel portion R2 of the present embodiment are formed by the silicon oxide film. Therefore, the light can suitably enter the bevel portion R2. The light receiver 16d can detect the bevel information, the warp information, the notch information, and the eccentricity amount information described above in the form of optical measurement data by the measurement of the light that has entered from the substrate 1a. The controller 17 can extract the bevel information, the warp information, the notch information, and the eccentricity amount information described above from the optical measurement data by calculation and analysis using the optical measurement data.

The bevel information is information relating to the shape of the bevel portion R2 of the substrate 1a and includes information relating to the profiles of the front face S1 and the rear face S2 of the bevel portion R2, for example. The warp information is information relating to the warp of the substrate 1a and includes information indicating whether the substrate 1a has a shape that is convex upward or a shape that is convex downward and information relating to the profiles of those convex shapes, for example. The notch information is information relating to the notch in the substrate 1a and includes information indicating the position of the notch before the rotation of the substrate 1a is started, for example. In this case, it becomes possible to calculate, with use of the notch information and the rotation speed of the substrate 1a, the position of the notch at a freely-selected time after the rotation of the substrate 1a is started. The eccentricity amount information is information relating to the eccentricity amount of the substrate 1a and includes information indicating a shift amount (eccentricity amount) between the central axis of the substrate 1a and a central axis of the stage 12, for example. The detector 16 of the present embodiment may detect the bevel information, the warp information, the notch information, and the eccentricity amount information in either form of the image data and the optical measurement data.

The bevel information, the warp information, the notch information, and the eccentricity amount information may be detected by a method other than the examples illustrated in FIGS. 3A and 3B. For example, the eccentricity amount information may be detected by a plurality of positioning mechanism units (not shown) provided in the processing chamber 11. When correction of causing the eccentricity amount to approach zero is performed before the processing of the processing target substrate 1, the controller 17 does not necessarily need to use the eccentricity amount information for the abovementioned control. Conversely, when the controller 17 performs the abovementioned control with use of the eccentricity amount information, the correction of causing the eccentricity amount to approach zero does not necessarily need to perform before the processing of the processing target substrate 1.

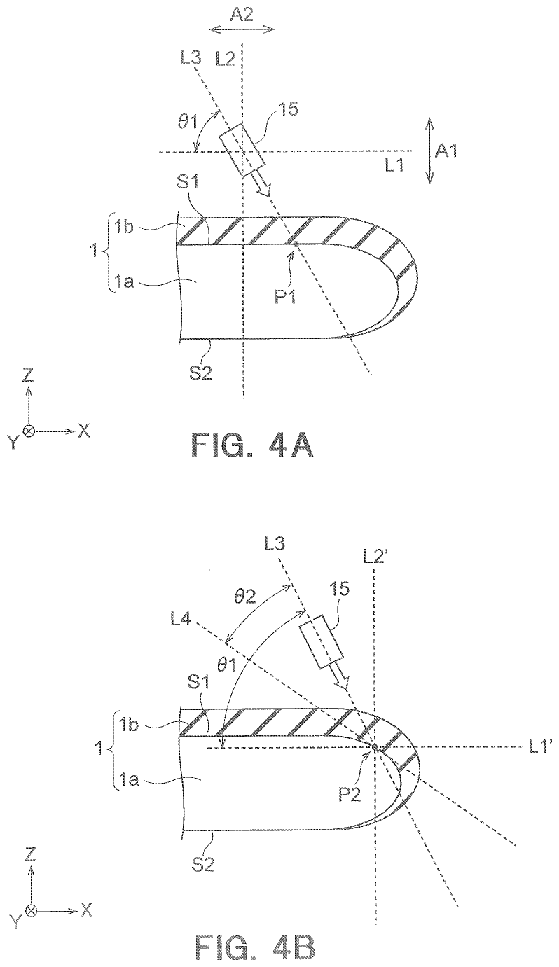

FIGS. 4A and 4B are cross-sectional views for describing the operation of the chemical solution supplier 15 of the first embodiment.

As with FIG. 1, FIG. 4A illustrates the nozzle of the chemical solution supplier 15 of the present embodiment. The chemical solution supplier 15 of the present embodiment discharges the chemical solution to the film 1b from the nozzle. In the description below, the nozzle is also referred to as “the nozzle 15”.

FIG. 4A illustrates a straight line L1, a straight line L2, and a straight line L3 that pass through a predetermined point in the nozzle 15. The positions of the straight lines L1, L2, and L3 indicate the position of the nozzle 15. Specifically, the straight line L1 extends to be parallel to an XY plane and extends in the radiation direction from a point on the central axis C (see FIG. 1). The distance between the substrate is and the straight line L1 is equivalent to the height of the nozzle 15 from the substrate 1a. The straight line L2 extends to be parallel to the Z direction, and the distance between the central axis C and the straight line L2 is equivalent to the distance of the nozzle 15 from the central axis C. The straight line L3 extends to be parallel to the direction in which the nozzle 15 extends, and coordinates of an intersecting point of the straight lines L1, L2, and L3 is equivalent to coordinates of a predetermined point in the nozzle 15.

FIG. 4A further illustrates A1 and A2 indicating moving directions of the nozzle 15. The nozzle 15 of the present embodiment is movable in the directions indicated by arrows A1, A2. The arrow A1 is parallel to the straight line L2. Therefore, the semiconductor manufacturing apparatus of the present embodiment can move the nozzle 15 in the up-down direction and change the height of the nozzle 15 from the substrate is by moving the nozzle 15 in the direction indicated by the arrow A1. The arrow A2 is parallel to the straight line L1. Therefore, the semiconductor manufacturing apparatus of the present embodiment can move the nozzle 15 in the radiation direction and change the distance of the nozzle 15 from the central axis C of the substrate is by moving the nozzle 15 in the direction indicated by the arrow A2.

FIG. 4A further illustrates an angle θ1 between the straight line L1 and the straight line L3. The nozzle 15 of the present embodiment can be rotated in the direction in which the angle θ1 changes. The angle θ1 is equivalent to the angle of the direction in which the nozzle 15 extends with respect to the front face S1 in the central portion R1 of the substrate 1a. In other words, the angle θ1 is equivalent to the angle of the nozzle 15. The semiconductor manufacturing apparatus of the present embodiment can not only change the position of the nozzle 15 but also change the angle of the nozzle 15.

FIG. 4A further illustrates an intersecting point P1 between the straight line L3 and the front face S1 of the substrate 1a. The chemical solution of the present embodiment is discharged from the nozzle 15 toward the intersecting point P1 and hits the film 1b positioned between the nozzle 15 and the intersecting point P1. As a result, the film 1b around the section hit by the chemical solution is etched by the chemical solution. The semiconductor manufacturing apparatus of the present embodiment can change the etching section of the film 1b by changing the position and the angle of the nozzle 15 and rotating the processing target substrate 1 by the rotational shaft 13. This makes it possible to etch the film 1b into a desired shape. The position of the intersecting point P1 of the present embodiment is near the cutting position of the film 1b described with reference to FIGS. 2B and 2C.

When the angle θ1 is 90 degrees, the nozzle 15 faces the −Z direction, and the chemical solution is discharged to a place directly below the nozzle 15. In this case, when the chemical solution is discharged to the film 1b on the central portion R1, there is a fear that the chemical solution that has hit the film 1b splashes to a place directly above the film 1b and the splashed chemical solution hits the nozzle 15. The same applies to a case where the angle θ1 is close to 90 degrees. Meanwhile, when the angle θ1 is close to 0 degrees, there is a fear that the chemical solution spreads to a wide range of the film 1b and the film 1b cannot be etched to a desired shape. Therefore, when the chemical solution is discharged to the film 1b on the central portion R1, it is desired that the angle θ1 be a value far from both of 90 degrees and 0 degrees. When the semiconductor manufacturing apparatus of the present embodiment discharges the chemical solution to the film 1b on the central portion R1, the angle θ1 is set to 45 degrees or a value close to 45 degrees. Meanwhile, when the chemical solution is discharged to the film 1b on the bevel portion R2, it may not be desirable to be set the angle θ1 to 45 degrees or a value close to 45 degrees as described below.

FIG. 4B illustrates the nozzle 15 of the present embodiment as with FIGS. 1 and 4A. FIG. 4B illustrates how the chemical solution is discharged to the film 1b on the bevel portion R2.

FIG. 4B illustrates an intersecting point P2 between the straight line L3 and the front face S1 of the substrate 1a. While the intersecting point P1 is positioned on the front face S1 of the central portion R1, the intersecting point P2 is positioned on the front face S1 of the bevel portion R2. In FIG. 4B, the chemical solution is discharged from the nozzle 15 toward the intersecting point P2 and hits the film 1b positioned between the nozzle 15 and the intersecting point P2. As a result, the film 1b around the section hit by the chemical solution is etched by the chemical solution.

FIG. 4B further illustrates a straight line L1′, a straight line L2′, and a straight line L4 that pass through the intersecting point P2. The straight line L1′ is parallel to the straight line L1 and extends from a point on the central axis C toward the intersecting point P2 in the radiation direction. The straight line L2′ is parallel to the straight line L2 and extends toward the intersecting point P2 in the up-down direction. The straight line L4 is in contact with the front face S1 of the bevel portion R2 at the intersecting point P2. Therefore, the straight line L4 serves as a tangent line of the bevel portion R2. The intersecting point P2 is the tangent point.

FIG. 4B further illustrates an angle θ1 between the straight line L1′ and the straight line L3 and an angle θ2 between the straight line L4 and the straight line L3. As described with reference to FIG. 4A, when the chemical solution is discharged toward the intersecting point P1, there is a fear that splashing and spreading of the chemical solution become a problem when the angle θ1 is close to 90 degrees or 0 degrees. Meanwhile, when the chemical solution is discharged toward the intersecting point P2, there is a fear that splashing and spreading of the chemical solution become a problem when the angle θ2 is close to 90 degrees or 0 degrees. The reason is because the front face S1 of the substrate 1a around the intersecting point P1 is parallel to the straight line L1′, and the front face S1 of the substrate 1a around the intersecting point P2 is parallel to the straight line L4. Therefore, in order to suppress the abovementioned problem around the intersecting point P1, the angle θ1 of the straight line L3 with respect to the straight line Lli needs to be taken into consideration. In order to suppress the abovementioned problem around the intersecting point P2, the angle θ2 of the straight line L3 with respect to the straight line L4 needs to be taken into consideration.

Therefore, when the semiconductor manufacturing apparatus of the present embodiment discharges the chemical solution to the film 1b on the bevel portion R2, it is desired that the angle θ2 be set to 45 degrees or a value close to 45 degrees. In this case, when the difference between the angle θ1 and the angle θ2 is expressed by Δθ (θ1−θ2=Δθ), the angle θ1 is set to 45 degrees+Δθ or a value close to 45 degrees+Δθ. Therefore, it is generally preferred that the angle θ1 when the chemical solution is discharged to the film 1b on the bevel portion R2 be set to be larger than the angle θ1 when the chemical solution is discharged to the film 1b on the central portion R1.

It is supposed that the distance between the intersecting point P1 and the nozzle 15 is desirably set to be a value D when the chemical solution is discharged to the film 1b on the central portion R1. In this case, it is desired that the distance between the intersecting point P2 and the nozzle 15 be also set to be the value D when the chemical solution is discharged to the film 1b on the bevel portion R2. Therefore, when the chemical solution is discharged to the film 1b on the bevel portion R2, it is desired that the nozzle 15 be moved in directions indicated by the arrows A1, A2 such that the distance between the intersecting point P2 and the nozzle 15 becomes the value D.

However, information relating to the shape of the bevel portion R2 is needed in order to suitably discharge the chemical solution to the film 1b on the bevel portion R2. This is because the position of the intersecting point P2 and the angle θ2 between the straight line L3 and the straight line L4 cannot be calculated when the shape of the bevel portion R2 is unknown. Therefore, the controller 17 of the present embodiment acquires the information (bevel information) relating to the shape of the bevel portion R2 from the detector 16 and controls the etching of the film 1b by the nozzle 15 based on the acquired information. Specifically, the controller 17 of the present embodiment controls the position and the angle of the nozzle 15 when the chemical solution is discharged to the film 1b on the bevel portion R2 based on the acquired information. This makes it possible to suitably etch the film 1b on the bevel portion R2. Specifically, it becomes possible to easily etch the film 1b on the bevel portion R2 with high accuracy.

In order to suitably discharge the chemical solution to the film 1b on the bevel portion R2, it is desired to also take information (warp information) relating to the warp of the substrate 1a into consideration. This is because the warp of the substrate 1a also affects the position of the intersecting point P2 and the angle θ2 between the straight line L3 and the straight line L4. Therefore, it is desired that the controller 17 of the present embodiment acquire the bevel information and the warp information from the detector 16 and control the etching of the film 1b by the nozzle 15 based on the acquired bevel information and warp information. In this case, the controller 17 of the present embodiment controls the position and the angle of the nozzle 15 when the chemical solution is discharged to the film 1b on the bevel portion R2 based on the acquired bevel information and warp information. This makes it possible to etch the film 1b on the bevel portion R2 in a further suitable manner.

In order to suitably discharge the chemical solution to the film 1b on the bevel portion R2, it is desired to also take information (eccentricity amount information) relating to the eccentricity amount of the substrate 1a into consideration. This is because the eccentricity amount of the substrate 1a also affects the position of the intersecting point P2 and the angle θ2 between the straight line L3 and the straight line L4. Therefore, it is desired that the controller 17 of the present embodiment acquire the bevel information and the eccentricity amount information from the detector 16 and control the etching of the film 1b by the nozzle 15 based on the acquired bevel information and eccentricity amount information. In this case, the controller 17 of the present embodiment controls the position and the angle of the nozzle 15 when the chemical solution is discharged to the film 1b on the bevel portion R2 based on the acquired bevel information and eccentricity amount information. This makes it possible to etch the film 1b on the bevel portion R2 in a further suitable manner. At this time, the controller 17 of the present embodiment may acquire the bevel information, the warp information, and the eccentricity amount information from the detector 16 and control the etching of the film 1b by the nozzle 15 based on the acquired bevel information, warp information, and eccentricity amount information.

The nozzle 15 illustrated in FIG. 4B is not tilted such that the nozzle 15 faces the direction of the central axis C, and the nozzle 15 is tilted such that the nozzle 15 faces the direction opposite to the central axis C. When the nozzle 15 is tilted so as to face the direction of the central axis C, there is a fear that the chemical solution discharged toward the intersecting point P2 spreads to the film 1b on the central portion R1 and etches the film 1b on the central portion R1. Therefore, it is desired that the nozzle 15 be tilted so as to face the direction opposite to the central axis C.

The controller 17 may use any standard when the controller 17 controls the position and the angle of the nozzle 15 with respect to the substrate 1a. For example, the position of the nozzle 15 with respect to the substrate 1a may be controlled by adjusting the positions of a certain point on the front face S1 of the central portion R1 and the nozzle 15. The position of the nozzle 15 with respect to the substrate 1a may be controlled by adjusting the positions of a certain point (for example, an alignment mark) in the film 1b on the central portion R1 and the nozzle 15. As above, the standard for controlling the position and the angle of the nozzle 15 may be in the substrate 1a or outside the substrate 1a.

[First Modification]

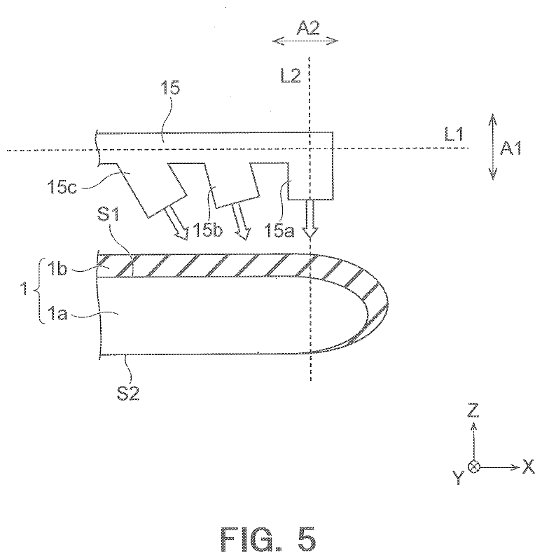

FIG. 5 is a cross-sectional view illustrating a structure of a semiconductor manufacturing apparatus of a first modification of the first embodiment.

The chemical solution supplier 15 of the present modification includes three nozzles 15a, 15b, 15c that discharge the chemical solution to the film 1b. The semiconductor manufacturing apparatus of the present modification can move the nozzles 15a to 15c together in the directions indicated by the arrows A1, A2, but cannot individually move the nozzles 15a to 15c. In the present modification, the positional relationship between the nozzles 15a to 15c is fixed.

Those nozzles 15a to 15c have different angles with respect to the straight line L1. Specifically, the angle of the nozzle 15a with respect to the straight line L1 is fixed to 90 degrees, and the nozzle 15a faces the −Z direction. The angle of the nozzle 15b with respect to the straight line L2 is fixed to be larger than 45 degrees and smaller than 90 degrees. The angle of the nozzle 15c with respect to the straight line L1 is fixed to 45 degrees. Any two of the nozzles 15a to 15c are examples of first and second nozzles.

In the present modification, the angles of the nozzles 15a to 15c cannot be changed. However, the semiconductor manufacturing apparatus of the present modification changes the nozzle to be used in accordance with the etching section of the film 1b such that the chemical solution is discharged to the film 1b from the nozzle 15a when the film 1b on the central portion R1 is etched and the chemical solution is discharged to the film 1b from the nozzle 15b or the nozzle 15c when the film 1b on the bevel portion R2 is etched. This makes it possible to suitably etch the film 1b on the bevel portion R2 as with the case of changing the angle of the nozzle.

When the chemical solution is discharged to the film 1b on the bevel portion R2, the controller 17 of the present modification acquires the bevel information from the detector 16 and selects the nozzle to be used from the nozzles 15a to 15c based on the acquired bevel information. The controller 17 of the present modification controls the operation of the chemical solution supplier 15 such that the chemical solution is discharged to the film 1b on the bevel portion R2 with use of the selected nozzle. For example, the positional relationship between the selected nozzle and the intersecting point P2 is adjusted. This makes it possible to suitably etch the film 1b on the bevel portion R2. According to the present modification, a mechanism that changes the angles of the nozzles 15a to 15c can be unnecessary.

The number of the nozzles of the chemical solution supplier 15 may be a number other than three. The angles of those nozzles may be an angle other than 90 degrees or an angle other than 45 degrees or may be an angle out of a range of from 45 degrees to 90 degrees. When the chemical solution is discharged to the film 1b on the bevel portion R2, the controller 17 of the present modification may acquire the bevel information, the warp information, and the eccentricity amount information from the detector 16, and the select nozzle to be used from the nozzles 15a to 15c based on the acquired bevel information, warp information, and eccentricity amount information.

[Second and Third Modifications]

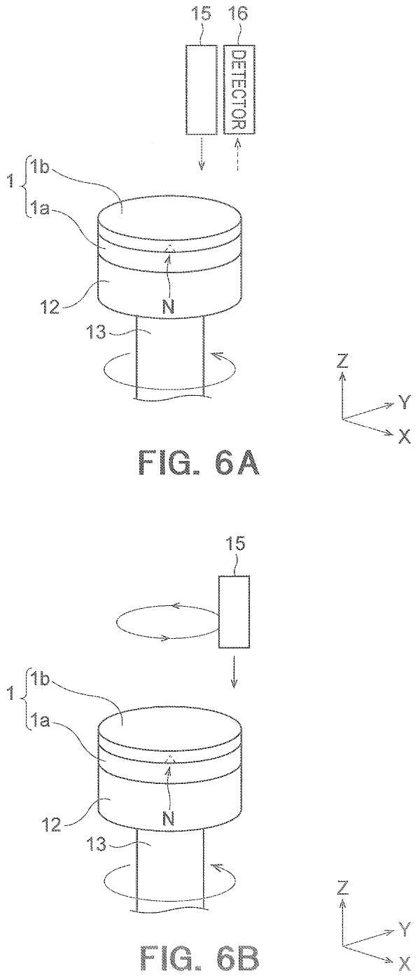

FIGS. 6A and 6B are perspective views illustrating structures of semiconductor manufacturing apparatuses of second and third modifications of the first embodiment.

FIG. 6A illustrates a structure of the semiconductor manufacturing apparatus of the second modification. The detector 16 of the present modification is disposed around the nozzle 15 in the processing chamber 11 (see FIG. 1). Therefore, the detector 16 of the present modification can detect information such as the bevel information from the processing target substrate 1 in the processing chamber 11. The detector 16 of the present modification is mounted on the nozzle 15 and moves with the nozzle 15. FIG. 6A further illustrates a notch N in the substrate 1a.

The shape and the warp of the processing target substrate 1 in the processing chamber 11 may be different from the shape and the warp of the processing target substrate 1 outside the processing chamber 11. For example, when the processing target substrate 1 is chucked by the stage 12, there is a possibility that the shape and the warp of the processing target substrate 1 changes. Therefore, the detector 16 of the present modification detects the bevel information, the warp information, the notch information, and the eccentricity amount information from the processing target substrate 1 in the processing chamber 11. This makes it possible to detect the bevel information, the warp information, the notch information, and the eccentricity amount information of which accuracy is high, and to etch the film 1b on the bevel portion R2 with a higher accuracy.

When the chemical solution is discharged to the film 1b on the bevel portion R2, there is a fear that the control of the etching becomes difficult when the chemical solution is discharged to the film 1b around the notch N. Therefore, it is desired that the controller 17 of the present modification control the etching of the film 1b by taking the notch information into consideration together with the bevel information. For example, the controller 17 of the present modification controls the etching of the film 1b around the notch N in an aspect different from the etching of the film 1b on the bevel portion R2 in other sections. This makes it possible to suitably etch the film 1b around the notch N.

FIG. 6B illustrates a structure of the semiconductor manufacturing apparatus of the third modification. The semiconductor manufacturing apparatus of the present modification can rotate the nozzle 15 above the processing target substrate 1. FIG. 6B illustrates the nozzle 15 that rotates about the rotational shaft C (see FIG. 1). The nozzle 15 of the present modification can discharge the chemical solution to the film 1b while rotating above the processing target substrate 1.

When the chemical solution is discharged to the film 1b on the bevel portion R2, the controller 17 of the present modification controls the position, the angle, and the rotation of the nozzle 15 based on the bevel information, the warp information, the notch information, and the eccentricity amount information. This makes it possible to suitably etch the film 1b on the bevel portion R2. For example, the controller 17 of the present modification can perform etching by the nozzle 15 while correcting the position of the nozzle 15 as needed in accordance with the warp of the substrate 1a and the shape of the bevel portion R2 by controlling the rotation of the nozzle 15 based on the bevel information, the warp information, the notch information, and the eccentricity amount information.

[Fourth and Fifth Modifications]

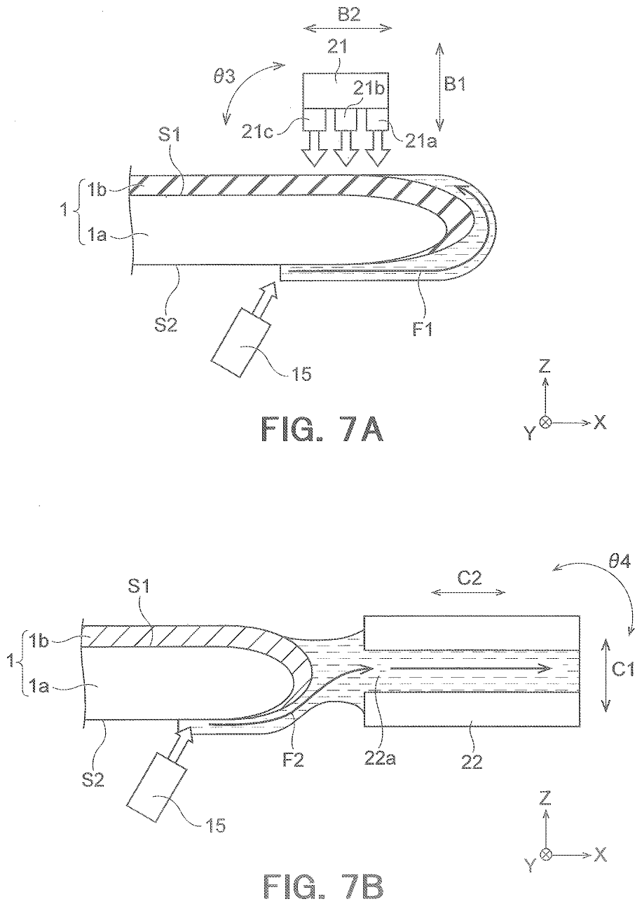

FIGS. 7A and 7B are cross-sectional views illustrating structures of semiconductor manufacturing apparatuses of fourth and fifth modifications of the first embodiment.

FIG. 7A illustrates the structure of the semiconductor manufacturing apparatus of the fourth modification. The semiconductor manufacturing apparatus of the present modification includes a gas supplier 21 that supplies gas to the film 1b in addition to the components illustrated in FIG. 1. The gas is inert gas such as nitrogen gas and noble gas, for example. The gas supplier 21 includes three gas nozzles 21a, 21b, 21c that discharge gas to the film 1b. The number of the gas nozzles of the gas supplier 21 may be a number other than three.

In the present modification, the film 1b is mainly formed on the front face S1 side of the substrate 1a, and the nozzle (chemical solution supplier) 15 discharges the chemical solution to the rear face S2 side of the substrate 1a. In FIG. 7A, the chemical solution hits the rear face S2 of the substrate 1a, reaches the bevel portion R2 along the rear face S2 of the substrate 1a, and etches the film 1b on the bevel portion R2 (see arrow F1). In this case, there is a fear that the chemical solution spreads to the film 1b on the central portion R1 and etches the film 1b on the central portion R1.

Therefore, the semiconductor manufacturing apparatus of the present modification supplies gas to the front face S1 side of the substrate 1a from the gas nozzles 21a to 21c as illustrated in FIG. 7A when the chemical solution is discharged to the rear face S2 side of the substrate 1a from the nozzle 15. This makes it possible to suppress a case where the chemical solution spreads to the film 1b on the central portion R1.

The gas nozzles 21a to 21c of the present modification can be moved together in the directions indicated by arrows B1, B2 and can be rotated together in the direction in which the angle θ3 changes. The semiconductor manufacturing apparatus of the present modification can move the gas nozzles 21a to 21c in the up-down direction by moving the gas nozzles 21a to 21c in the direction indicated by the arrow B1. The semiconductor manufacturing apparatus of the present modification can move the gas nozzles 21a to 21c in the radiation direction by moving the gas nozzles 21a to 21c in the direction indicated by the arrow B2. The semiconductor manufacturing apparatus of the present modification can control the angles of the gas nozzles 21a to 21c by changing the angle θ3.

It is desired that the gas nozzles 21a to 21c of the present modification perform discharging to the film 1b around a boundary between the central portion R1 and the bevel portion R2. This makes it possible to effectively protect the film 1b on the central portion R1 from the chemical solution. In this case, the suitable positions and angles of the gas nozzles 21a to 21c change in accordance with the shape of the bevel portion R2, the warp of the substrate 1a, the position of the notch N, and the like. Therefore, when the film 1b on the bevel portion R1 is etched, the controller 17 of the present modification controls the positions and the angles of the gas nozzles 21a to 21c based on the bevel information, the warp information, the notch information, and the eccentricity amount information. This makes it possible to suitably control the etching of the film 1b.

FIG. 7B illustrates the structure of the semiconductor manufacturing apparatus of the fifth modification. The semiconductor manufacturing apparatus of the present modification includes a chemical solution sucker 22 that sucks the chemical solution supplied to the film 1b in addition to the components illustrated in FIG. 1. The chemical solution sucker 22 includes a sucking nozzle 22a having an opening portion that sucks the chemical solution supplied to the film 1b. It is desired that the sucking nozzle 22a be formed by a material having excellent wettability for the chemical solution and having the tolerance to the chemical solution. The chemical solution sucker 22 may include two plates having a gap that sucks the chemical solution supplied to the film 1b instead of the sucking nozzle 22a.

In the present modification, the film 1b is mainly formed on the front face S1 side of the substrate 1a, and the nozzle (chemical solution supplier) 15 discharges the chemical solution to the rear face S2 side of the substrate 1a. In FIG. 7B, the chemical solution hits the rear face S2 of the substrate 1a, reaches the bevel portion R2 along the rear face S2 of the substrate 1a, and etches the film 1b on the bevel portion R2 (see arrow F2). In this case, there is a fear that the chemical solution spreads to the film 1b on the central portion R1 and etches the film 1b on the central portion R1.

Therefore, the semiconductor manufacturing apparatus of the present modification sucks, by the sucking nozzle 22a, the chemical solution that has reached the bevel portion R2 and been supplied to the film 1b as illustrated in FIG. 7B when the chemical solution is discharged to the rear face S2 side of the substrate 1a from the nozzle 15. This makes it possible to suppress a case where the chemical solution spreads to the film 1b on the central portion R1. In FIG. 7B, a meniscus bridge of the chemical solution is formed between the bevel portion R2 and the sucking nozzle 22a, and the chemical solution is sucked into the sucking nozzle 22a through the meniscus bridge.

The sucking nozzle 22a of the present modification can be moved in the directions indicated by arrows C1, C2 and can be rotated in the direction in which the angle θ4 changes. The semiconductor manufacturing apparatus of the present modification can move the sucking nozzle 22a in the up-down direction by moving the sucking nozzle 22a in the direction indicated by the arrow C1. The semiconductor manufacturing apparatus of the present modification can move the sucking nozzle 22a in the radiation direction by moving the sucking nozzle 22a in the direction indicated by the arrow C2. The semiconductor manufacturing apparatus of the present modification can control the angle of the sucking nozzle 22a by changing the angle θ4.

It is desired that the sucking nozzle 22a of the present modification suck the chemical solution existing on the bevel portion R2. This makes it possible to effectively protect the film 1b on the central portion R1 from the chemical solution. In this case, the suitable position and angle of the sucking nozzle 22a change in accordance with the shape of the bevel portion R2, the warp of the substrate 1a, the position of the notch N, and the like. Therefore, when the film 1b on the bevel portion R1 is etched, the controller 17 of the present modification controls the position and the angle of the sucking nozzle 22a based on the bevel information, the warp information, the notch information, and the eccentricity amount information. This makes it possible to suitably control the etching of the film 1b.

As above, the semiconductor manufacturing apparatus of the present embodiment detects the bevel information, the warp information, the notch information, and the eccentricity amount information of the processing target substrate 1 from the detector 16 and controls the processing of the film 1b on the bevel portion R2 by the controller 17 based on the information detected by the detector 16. Therefore, the present embodiment makes it possible to suitably process the film 1b provided on the bevel portion R2.

### Second Embodiment

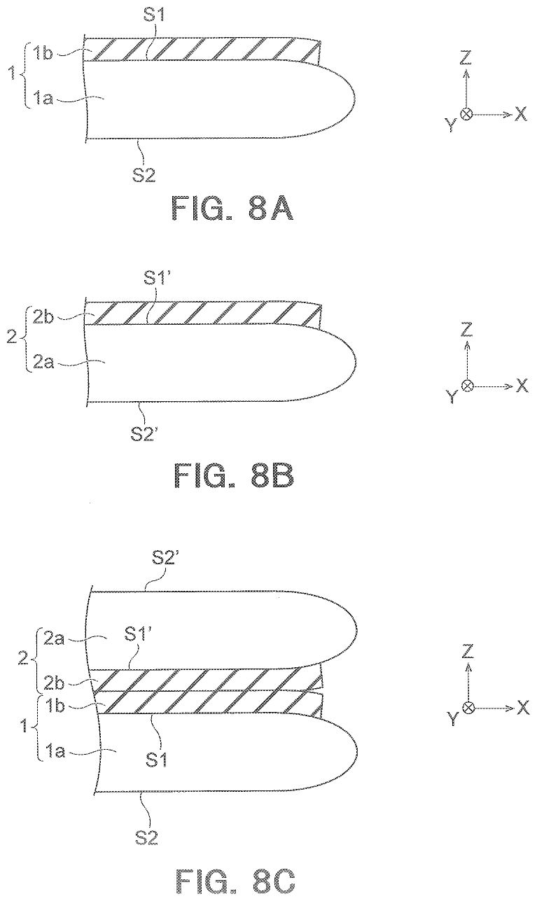

FIGS. 8A to 8C are cross-sectional views illustrating a method of manufacturing a semiconductor device of a second embodiment.

FIG. 8A illustrates the abovementioned processing target substrate 1. The processing target substrate 1 includes the substrate 1a and the film 1b provided on the substrate 1a. FIG. 8A illustrates the front face (upper face) S1 of the substrate 1a and the rear face (lower face) S2 of the substrate 1a. As described above, the substrate 1a includes the central portion R1 having the front face S1 and the rear face S2 that are generally flat, and the bevel portion R2 having the front face S1 and the rear face S2 that are curved (see FIG. 1). In the present embodiment, the film 1b is formed on the substrate 1a, and the film 1b is etched by the semiconductor manufacturing apparatus of the first embodiment. FIG. 8A illustrates the processing target substrate 1 after the etching.

FIG. 8B illustrates a processing target substrate 2. The processing target substrate 2 includes a substrate 2a and a film 2b provided on the substrate 2a. FIG. 8B illustrates a front face (upper face) S1′ of the substrate 2a and a rear face (lower face) S2′ of the substrate 2a. As with the substrate 1a, the substrate 2a includes a central portion having the front face S1′ and the rear face S2′ that are generally flat, and a bevel portion having the front face S1′ and the rear face S2′ that are curved. The properties of the substrate 2a and the film 2b are similar to the properties of the substrate 1a and the film 2b. In the present embodiment, the film 2b is formed on the substrate 2a, and the film 2b is etched by the semiconductor manufacturing apparatus of the first embodiment. FIG. 8B illustrates the processing target substrate 2 after the etching. The etching of the film 2b can be performed as with the etching of the film 1b.

In the present embodiment, the processing target substrate 1 illustrated in FIG. 8A and the processing target substrate 2 illustrated in FIG. 8B are bonded together (FIG. 8C). Specifically, the substrate 1a and the substrate 2a are bonded together over the films 1b, 2b such that the film 1b, the film 2b, and the substrate 2a are laminated on the substrate 1a in order. Therefore, in FIG. 8C, a lower face of the film 2b is bonded to an upper face of the film 1b. The front face S1′ of the substrate 2a is a lower face of the substrate 2a in FIG. 8C, and the rear face S2′ of the substrate 2a is an upper face of the substrate 2a in FIG. 8C.

Then, the substrates 1a, 2a are removed or thinned as needed. As above, the semiconductor device of the present embodiment is manufactured.

The processing target substrate 1 of the present embodiment is etched such that the film 1b remains on the bevel portion R2 of the substrate 1a (FIG. 8A). Similarly, the processing target substrate 2 of the present embodiment is etched such that the film 2b remains on the bevel portion of the substrate 2a (FIG. 8B). Therefore, the present embodiment makes it possible to suitably bond the processing target substrate 1 and the processing target substrate 2 together (FIG. 8C).

The processing target substrate 1 of the present embodiment may be etched by the semiconductor manufacturing apparatus of any of the first to fifth modification. Similarly, the processing target substrate 2 of the present embodiment may be etched by the semiconductor manufacturing apparatus of any of the first to fifth modification.

Each of the films 1b, 2b of the present embodiment may include a memory cell array and a CMOS circuit that controls the memory cell array. This makes it possible to manufacture the semiconductor device that functions as a semiconductor memory. The semiconductor device of the present embodiment may be manufactured by bonding together three or more processing target substrates.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A semiconductor manufacturing apparatus comprising:
a processor configured to process a film provided on an end portion of a substrate;
a detector configured to detect information relating to a shape of the end portion of the substrate; and
a controller configured to control the processing of the film by the processor, based on the information relating to the shape of the end portion of the substrate.

2. The apparatus of claim 1, wherein
the processor etches the film by a liquid, and
the controller controls the etching of the film by the processor.

3. The apparatus of claim 2, wherein the controller controls the etching of the film by the processor such that the film remains on the end portion of the substrate.

4. The apparatus of claim 2, wherein the processor includes a nozzle configured to discharge the liquid to the film.

5. The apparatus of claim 4, wherein the controller controls the etching of the film by controlling a position or an angle of the nozzle with respect to the substrate.

6. The apparatus of claim 4, wherein the nozzle discharges the liquid while rotating above the substrate.

7. The apparatus of claim 2, wherein
the processor includes a first nozzle having a first angle with respect to the substrate and configured to discharge the liquid to the film, and a second nozzle having a second angle different from the first angle with respect to the substrate and configured to discharge the liquid to the film, and
the controller selects the first nozzle or the second nozzle based on the information relating to the shape of the end portion of the substrate, and controls the etching of the film by the selected nozzle.

8. The apparatus of claim 2, further comprising a gas supplier configured to supply gas to the film.

9. The apparatus of claim 8, wherein
the gas supplier includes a gas nozzle configured to discharge the gas to the film, and
the controller controls the etching of the film by controlling a position or an angle of the gas nozzle with respect to the substrate.

10. The apparatus of claim 8, wherein
the film is provided on a first face side of the substrate,
the processor supplies the liquid to a second face side of the substrate, and
the gas supplier supplies the gas to the first face side of the substrate.

11. The apparatus of claim 2, further comprising a sucker configured to suck the liquid supplied to the film.

12. The apparatus of claim 11, wherein
the sucker includes a sucking nozzle configured to suck the liquid supplied to the film, and
the controller controls the etching of the film by controlling a position or an angle of the sucking nozzle with respect to the substrate.

13. The apparatus of claim 12, wherein the controller controls the position or the angle of the sucking nozzle with respect to the substrate such that the liquid existing on the end portion of the substrate is sucked.

14. The apparatus of claim 1, wherein
the detector further detects information relating to a warp and/or an eccentricity amount of the substrate; and
the controller controls the processing of the film by the processor, based on the information relating to the shape of the end portion of the substrate and the information relating to the warp and/or the eccentricity amount of the substrate.

15. The apparatus of claim 1, wherein
the detector further detects information relating to a notch in the substrate, and
the controller controls the processing of the film by the processor, based on the information relating to the shape of the end portion of the substrate and the information relating to the notch in the substrate.

16. The apparatus of claim 1, wherein the detector detects the information relating to the shape of the end portion of the substrate, in a form of image data or optical measurement data.

17. The apparatus of claim 1, further comprising a container configured to contain the substrate,
wherein
the processor processes the film provided on the end portion of the substrate, when the substrate is contained in the container; and
the detector detects the information relating to the shape of the end portion of the substrate, when the substrate is contained in the container.

18. The apparatus of claim 1, wherein the end portion of the substrate is a bevel portion of the substrate.

19. A method of manufacturing a semiconductor device, comprising:
processing, by a processor, a film provided on an end portion of a substrate;
detecting, by a detector, information relating to a shape of the end portion of the substrate; and
controlling, by a controller, the processing of the film by the processor, based on the information relating to the shape of the end portion of the substrate.

20. The method of claim 19, further comprising bonding the substrate to another substrate via the film.
